(19) United States
(12) Patent Application Publication
(10) Pub. No.: US 2018/0299765 A1
(43) Pub. Date: Oct. 18, 2018

(54) EXTREME ULTRAVIOLET LITHOGRAPHY (EUVL) REFLECTIVE MASK

(71) Applicant: GLOBALFOUNDRIES INC., Grand Cayman (KY)

(72) Inventors: SherJang Singh, Clifton Park, NY (US); Sunil K. Singh, Mechanicville, NY (US); Sohan S. Mehta, Saratoga Springs, NY (US)

(21) Appl. No.: 15/485,498

(22) Filed: Apr. 12, 2017

(51) Int. Cl. G03F 1/24; C23C 16/02; G03F 1/54; G03F 1/52; G03F 1/46; G03F 1/80; G03F 1/60

(52) U.S. Cl. CPC G03F 1/24; C23C 16/0227; G03F 1/54; G03F 1/60; G03F 1/46; G03F 1/80; G03F 1/52

(57) ABSTRACT

A reflective mask with an embedded absorber pattern is provided. The reflective mask may include a low thermal expansion material (LTEM) substrate. A pair of reflective stacks may be included, each reflective stack having a first respective top surface extending from the LTEM substrate to a first extent. A fill stack is between the pair of reflective stacks, the fill stack having a second top surface extending from the LTEM substrate to a second extent, the second extent being below the first extent of the pair of reflective stacks. An extended portion of each of the pair of reflective stacks is above the fill stack thereby forming a recess well between the pair of reflective stacks, the recess well having substantially vertical walls separated by the second top surface of the fill stack. An absorber layer lining the recess well.

### BACKGROUND

The present disclosure relates generally to a photolithography mask, and, more specifically, to an extreme ultraviolet lithography reflective mask and fabrication methods thereof.

Typical EUV photomasks create a mask pattern with an absorber layer patterned on top of a reflective stack. EUV photomasks are illuminated at an angle to its normal in order to reflect the mask pattern onto a wafer. This non-orthogonal illumination of the EUV mask causes shadowing of the lines that are perpendicular to the incident beam. Further, telecentricity errors appear as a result in a pattern shift that occurs through focusing. Also, there is a loss in image contrast due to anodization by a reflective mask coating of the reflective stack.

### SUMMARY

A first aspect of the disclosure provides a reflective mask having a reflective pattern, and an absorber pattern embedded within the reflective pattern with a top surface of the absorber pattern being at or below a top surface of the reflective pattern.

A second aspect of the disclosure provides a reflective mask including: a low thermal expansion material (LTEM) substrate; a pair of reflective stacks, each reflective stack having a first respective top surface extending from the LTEM substrate to a first extent; a fill stack between the pair of reflective stacks, the fill stack having a second top surface extending from the LTEM substrate to a second extent, the second extent being below the first extent of the pair of reflective stacks, wherein an extended portion of each of the pair of reflective stacks are above the fill stack thereby forming a recess well between the pair of reflective stacks, the recess well having substantially vertical walls separated by the second top surface of the fill stack; and an absorber layer lining the recess well.

A third aspect of the disclosure provides a method including depositing a fill material onto an extreme ultraviolet (EUV) etched mask, the EUV etched mask including a low thermal expansion material (LTEM) substrate, a pair of reflective stacks, and a trench exposing the LTEM substrate between the pair of reflective stacks, the fill material filling the trench; forming a recess well by etching the fill material; depositing an absorber layer over the pair of reflective stacks and in the recess well, wherein a gap remains within the recess well; depositing a sacrificial fill material over the absorber layer and filling the gap; planarizing the sacrificial fill material to a top surface of the pair of reflective stacks; and removing the sacrificial fill material in the gap.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 is a cross-sectional view of a portion of a prior art lithography mask, as may be used in an extreme ultraviolet lithography (EUVL) process.

FIG. 2 is a cross-sectional view of an initial mask structure in a stage of fabrication, according to embodiments of the present disclosure.

FIG. 3 is a cross-sectional view of a mask structure in an intermediate stage of fabrication, according to embodiments of the present disclosure.

FIG. 4 is a cross-sectional view of a mask structure in an intermediate stage of fabrication, according to embodiments of the present disclosure.

FIG. 5 is a cross-sectional view of a mask structure in an intermediate stage of fabrication, according to embodiments of the present disclosure.

FIG. 6 is a cross-sectional view of a mask structure in an intermediate stage of fabrication, according to embodiments of the present disclosure.

FIG. 7 is a cross-sectional view of a mask structure in an intermediate stage of fabrication, according to embodiments of the present disclosure.

FIG. 8 is a cross-sectional view of an illustrative embodiment of a reflective mask, according to aspects of the present disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

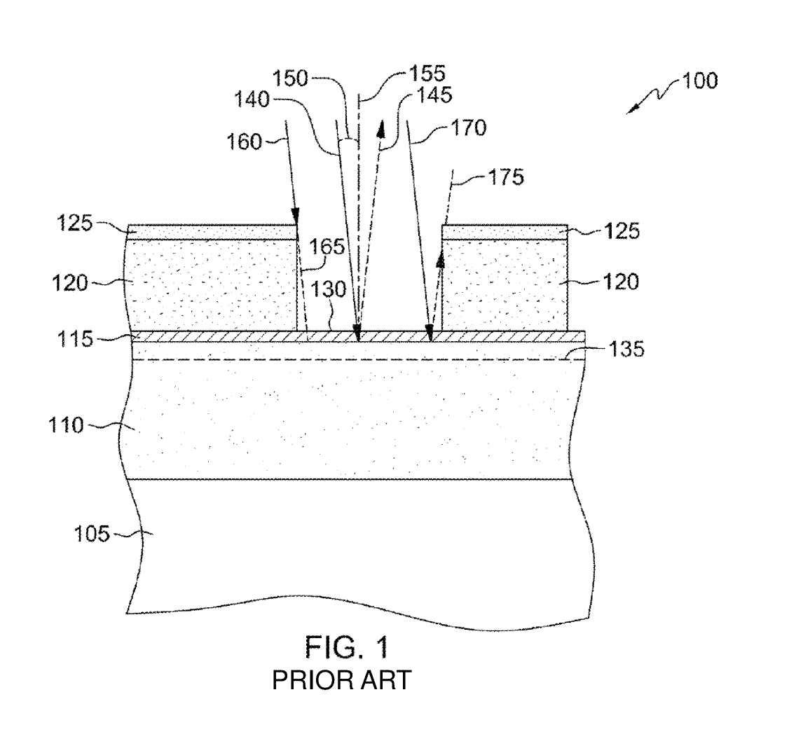

FIG. 1 is a cross-sectional view of a portion of a prior art reflective mask. As shown, lithography mask structure 100 includes substrate 105, such as a quartz substrate or a low thermal expansion material (LTEM) substrate, with one or more reflective layers 110 over the substrate, such as multiple interleaved molybdenum and silicon layer pairs. Capping layer 115 may frequently be included to protect the one or more reflective layers 110 from being damaged during etching or mask cleaning processes. A thick absorber film 120 is disposed over capping layer 115, with portions of thick absorber film 120 having been etched or otherwise removed to form the mask pattern, leaving exposed one or more reflective surfaces 130 of the mask structure. As used in extreme ultra-violet lithography (EUVL) processes, thick absorber film 120 portions represent lines or other desired regions or structures of a circuit structure on a wafer to be protected, while spaces between thick absorber film 120 portions represent the spaces between circuit structure features, and thus are the spaces to be etched on a wafer or a layer over the wafer. Thick absorber film 120 also includes a deep ultraviolet (DUV) anti-reflective coating (ARC) 125, which facilitates inspection of the EUVL mask pattern by a deep-ultraviolet pattern inspection tool.

In a EUVL process employing a mask structure such as that depicted in FIG. 1, EUV light 140, such as light at about 13.5 nanometers (nm), may be provided incident on lithography mask structure 100 at an angle 150 to normal 155. Incident EUV light may reflect at surface 130, but may alternatively pass through surface 130 and reflect instead at a deeper layer within the one or more reflective layers 110. Constructive interference between individual light waves reflected at multiple different layers gives rise to an “effective reflection plane” 135 below surface 130. Reflected EUV light 145 is then transmitted to a wafer. This transmission may be accomplished via a series of mirrors (not shown). However, some EUV light that should be incident on reflecting surface 130 may instead be blocked by a portion of thick absorber film 120, as illustrated by blocked EUV light wave 160, which should otherwise have continued along path 165 to be reflected. As well, some EUV light may be reflected but subsequently blocked by a portion of thick absorber film 120, as illustrated by light beam 170 whose reflected beam 175 is blocked such that it cannot be transmitted to a wafer undergoing processing. This undesired blocking of EUV light may cause several types of defects in wafer patterning, including shadowing of lines on a wafer (leading to some lines being formed wider than designed on the final wafer), portions of printed patterns shifting from their designed positions, and some contrast loss between etched spaces and pattern lines (which may lead to lines not having well-defined edges).

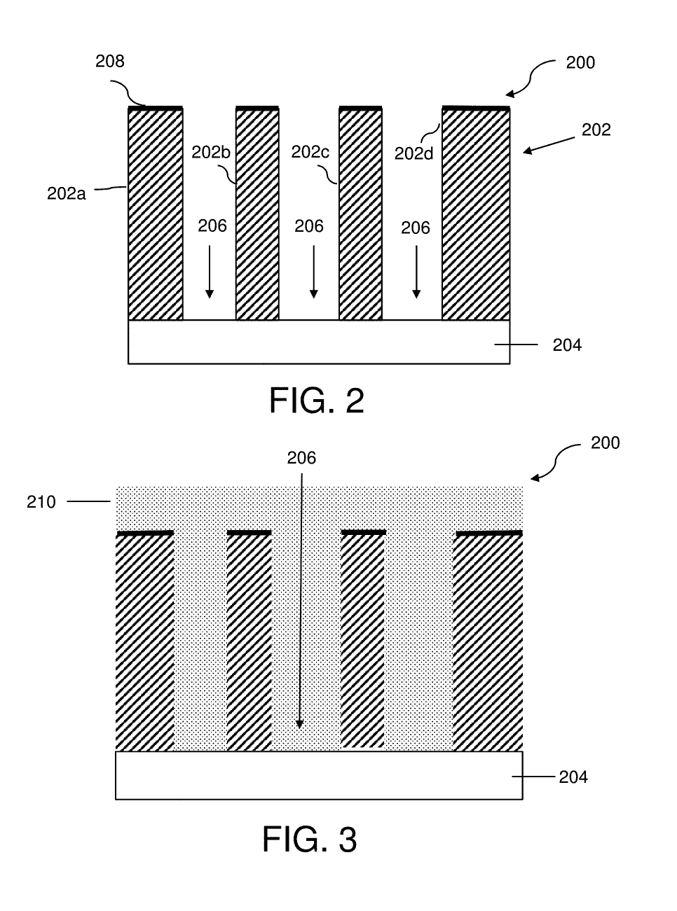

FIGS. 2-8 show steps of an illustrative method of fabricating an illustrative mask according to aspects described herein.

FIG. 2 is a cross-sectional view of initial structure 200, which may be fabricated with methods known in the art. For example, initial structure 200 has a reflective stack 202 with reflector regions 202a-d that create a reflective pattern. In an illustrative embodiment, initial structure 200 may be fabricated by starting with a multilayer reflective blank (not shown) having multiple layers of interleaved molybdenum and silicon pairs as reflective stacks 202, then depositing an e-beam resist coating and etching the multilayer blank with methods such as e-beam mask writing, and then removing the e-beam resist coating. That is, reflective stacks 202 may each include at least one molybdenum layer and one silicon layer. As discussed elsewhere herein, reflective stack 202 can be formed, e.g., as a bulk layer on substrate 204 before being patterned and removed to form reflector regions 202a-d of reflective stack 202.

In the illustrative embodiment shown in FIG. 2, initial structure 200 is an EUV etched binary mask having substrate 204 as an LTEM substrate, reflective stack 202, and trenches 206 between reflector regions 202a-d of reflective stack 202. As used herein, “binary mask” indicates a mask in which light is reflected through clear multilayer areas and completed absorbed by absorber areas, i.e., absorber areas have zero reflectivity. A binary mask is different than a phase shift mask in which some reflected light is also reflected from the absorber areas. LTEM substrate 204 may include any substrate having have an expansion ratio of less than 5 parts per billion per degree Celsius (ppb/° C.). LTEM substrate 204 may include, for example, quartz. Trenches 206 can expose areas of LTEM substrate 204, and may be formed using any now known or later developed technique. That is, trenches 206 are etched to and expose LTEM substrate 204 which eliminates any reflection therefrom, and which is in contrast to conventional phase shift mask formation techniques. Further, in the illustrative embodiment shown, reflective stack 202 has capping layer 208, such as a ruthenium (Ru) cap. In other embodiments, capping layer 208 may include a silicon (Si) cap, or a titanium oxide (TiO₂) cap. Etching generally refers to the removal of material or structures formed on the substrate, and is often performed with a mask in place so that material may selectively be removed from certain areas of the substrate, while leaving the material unaffected, in other areas of the substrate. There are generally two categories of etching, (i) wet etch, and (ii) dry etch. Wet etch is performed with a solvent (such as an acid or a base) which may be chosen for its ability to selectively dissolve a given material (such as oxide), while, leaving another material (such as polysilicon or nitride) relatively intact. This ability to selectively etch given materials is fundamental to many semiconductor fabrication processes. A wet etch will generally etch a homogeneous material (e.g., nitride) isotopically, but a wet etch may also etch single-crystal materials (e.g. silicon wafers) anisotopically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotopic. Ion milling, or sputter etching, bombards the wafer with energetic ions of noble gases which approach the wafer approximately from one direction, and therefore this process is highly anisotopic. Reactive-ion etching (RIE) operates under conditions intermediate between sputter and plasma etching and may be used to produce deep, narrow features, such as STI trenches.

FIG. 3 shows an intermediate structure as a result of depositing fill material 210 on initial structure 200. Fill material 210 fills trenches 206 (FIG. 2) and covers the exposed areas of substrate 204. In illustrative embodiments, fill material 210 may be made of materials such as but not limited to: hydrogen silsesquioxane (HSQ), methylsilsesquioxane (MSQ), or nanocluster silica (NCS). As used herein, the term “deposition” or “depositing” generally refers to any currently known or later developed technique appropriate for fill material 210, or other materials to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and/or evaporation.

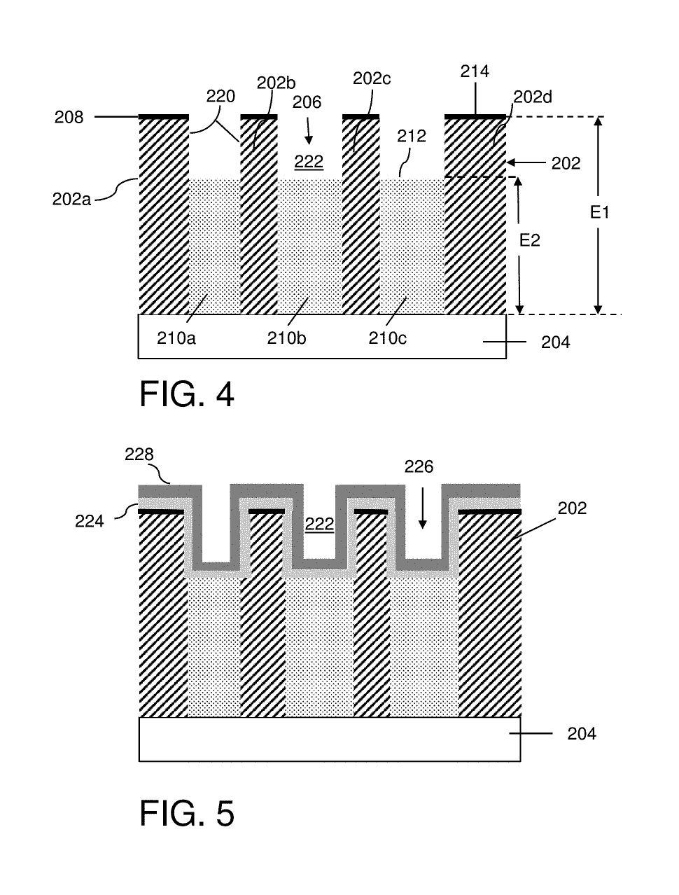

FIG. 4 shows an intermediate structure as a result of etching fill material 210 to expose a portion of reflective stack 202 while remnants, e.g., remnants 210a-c, of fill material 210 remain in trenches 206. Capping layer 208 may be used as an etch stop in this step. In an example embodiment, fill material 210 has top surface 212 that is below top surface 214 of reflective stacks 202. In one embodiment, top surface 212 is approximately 50 to 150 nanometers (nm) below top surface 214 of reflective stacks 202, i.e., recess wells have a depth of between approximately 50 to 150 nm below the fully etched multi-layer mirror of reflective stacks 202. As used herein, “approximately” indicates +/−10% of each value stated in a range. For example, reflective stacks 202 each have top surface 214 that extends to first extent E1 from substrate 204, and fill stacks 210 have top surface 212 that extends to second extent E2 below first extent E1. Thus, portions (which may include side surfaces 220 and top surfaces 214) of each reflector region 202a-d of reflective stack 202 can extend above the plurality of fill remnants 210a-c, which results in formation of recess wells 222. Recess wells 222 are formed from top surface 212 of fill material stacks 210 separating side surfaces 220 of adjacent reflective stacks 202. In an example embodiment, side surfaces 220 are substantially vertical and top surface 212 is substantially horizontal, e.g., within +/−5° of each. In another embodiment, fill material 210 has a top surface 212 that is below an effective reflective plane, as created by reflector stacks 202.

FIG. 5 shows an intermediate structure after depositing an absorber layer 224 over the extended portions of reflective stack 202 and in recess wells 222. In example embodiments, absorber layer 224 may be made of a tantalum-based compound, such as tantalum, tantalum nitride or tantalum-boron nitride, or other compounds including platinum, chromium, nickel, palladium, silver, tin, indium or cadmium. Absorber layer 224 has a thickness that does not fill recess wells 222. That is, recess wells 222 are initially sized such that after absorber layer 224 (and anti-reflective coating 228) is deposited, a gap 226 remains within each recess well 222.

Absorber layer 224 absorbs EUV light to prevent it from reaching fill material 210 as fill material 210 may not be a good absorber of EUV light and may degrade over time if exposed thereto. Further, anti-reflective coating 228 may be optionally deposited over absorber layer 224. As noted, recess wells 222 are initially sized such that absorber layer 224 and anti-reflective coating 228 do not fill recess wells, and a gap 226 remains in each recess wells 222. Anti-reflective coating 228 may include any now known or later developed layer capable of reducing reflection commonly used in semiconductor device fabrication masks such as but not limited to tantalum oxide (TaO), tantalum oxynitride (TaON), and tantalum borate (TaBO).

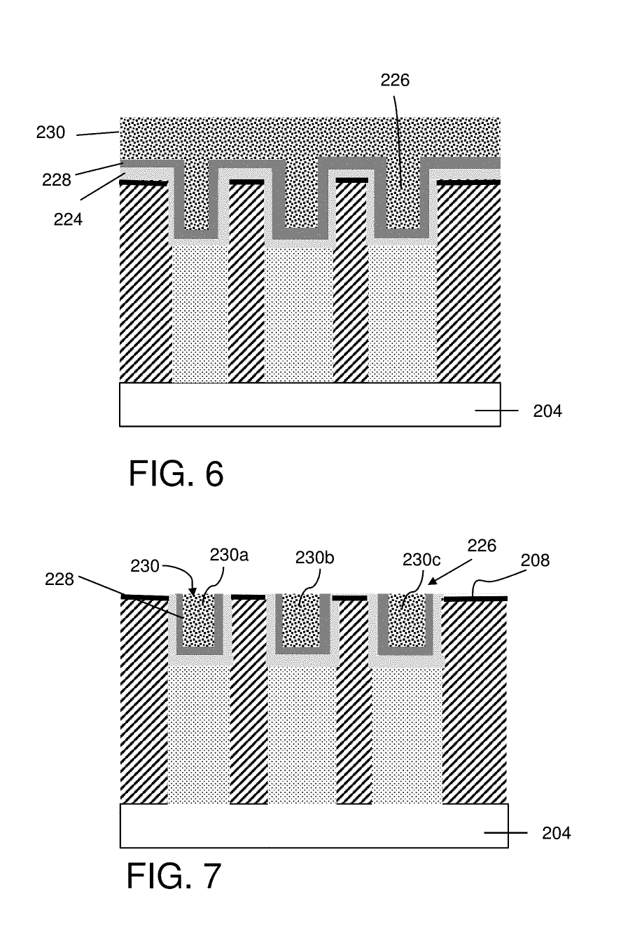

FIG. 6 shows an intermediate structure after depositing a sacrificial fill material 230 over absorber layer 224 and anti-reflective coating 228, and filling gaps 226. Sacrificial fill material 230 may include, for example, silicon oxide.

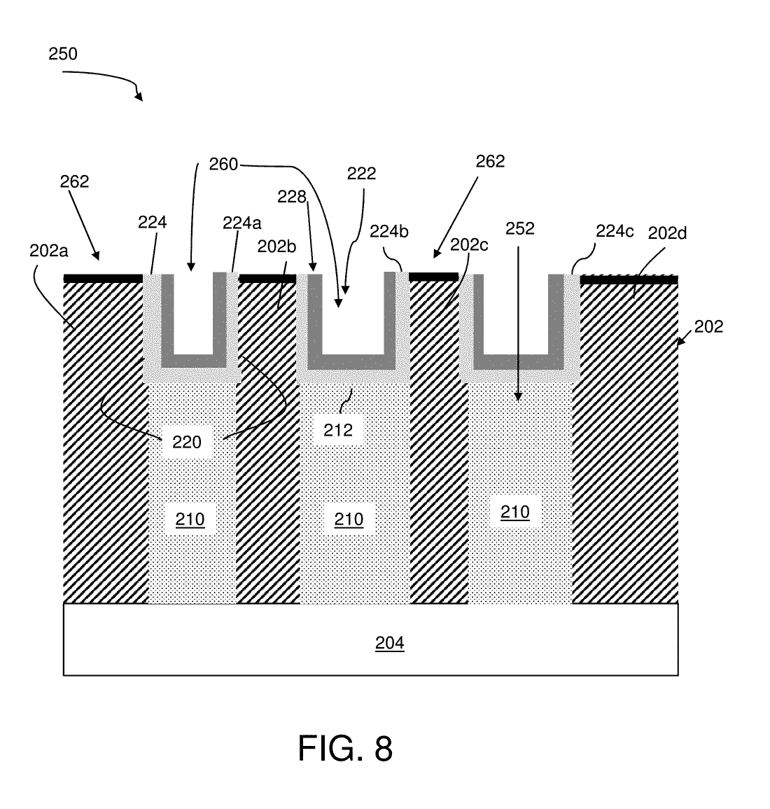

FIG. 7 shows an intermediate structure after planarizing sacrificial fill material 230, e.g., via chemical mechanical polishing (CMP), such that an upper surface of sacrificial fill material 230 is substantially coplanar with a top surface of capping layer 208. That is, planarizing absorber layer 224 and anti-reflective coating 228 above capping layer 208 are removed by planarizing. In the illustrative embodiment shown, sacrificial fill material remnants 230a-c remain in gaps 226.

FIG. 8 shows a resulting reflective mask 250 according to aspects of the present disclosure. Reflective mask 250 results from etching to remove sacrificial fill material 230 (FIG. 7) in gaps 226 (FIG. 7). In the illustrative embodiment shown in FIG. 8, reflective mask 250 includes an absorber pattern 260 embedded within a reflective pattern 262. That is, a top surface of absorber pattern 260 is at or below a top surface of reflective pattern 262. Absorber pattern 260 has zero reflectivity to incident light wave, i.e., it completely absorbs light impinging thereon, creating a binary mask with reflective pattern 262. Reflective pattern 262 includes reflective stacks 202, and absorber pattern 260 includes absorber stacks 252 positioned between reflective stacks 202, i.e., extending horizontally therebetween. Absorber stacks 252 include absorber layer 224 lining each recess well 222, anti-reflective coating 228 (where provided) and fill material 210. Absorber layer 224 covers vertical side surfaces 220 of adjacent reflective regions 202a-d of reflective stacks 202 (e.g., reflective region 202a is adjacent to reflective region 202b, and reflective region 202b is adjacent to reflective regions 202a and 202c, etc.).

In other words, reflective mask 250 may be defined to include pair of reflective stacks 202 with reflector regions 202a, 202b, 202c, and 202d, configured into reflective pattern 262. Reflective stack 202 may extend from substrate 204, for example, an LTEM substrate 204. Each reflective stack 202 has a first respective top surface 214 extending from the LTEM substrate to a first extent E1 (FIG. 4). A fill stack 210 is positioned between pair of reflective stacks 202, the fill stack having a second top surface 212 extending from LTEM substrate 204 to second extent E2, the second extent being below the first extent of the pair of reflective stacks. An extended portion of each of pair of reflective stacks 202 are above fill stack 210 thereby forming a recess well 222 between pair of reflective stacks 202, the recess well having substantially vertical walls separated by second top surface 212 of fill stack 210. Absorber layer 224 lines recess wells 222.

Absorber layer 224 may include absorber regions 224a, 224b, and 224c configured into an absorber pattern 260. In an example embodiment, anti-reflective layer 228 overlays absorber layer 224. Together, fill material 210, absorber layer 224, and (optionally) anti-reflective coating 228 can be considered an absorber stack 252. However, a person having ordinary skill in the art will appreciate that an absorber stack can include various kinds of layers.

Conventional masks either employ an absorber deposited on top of the multilayer reflector and then patterned over it (i.e., the absorber is a raised feature that leads to unwanted mask 3D defects etc.), or they provide partially light absorbing embedded absorber areas. In contrast, embodiments of the disclosure provide reflective mask 250 with embedded absorber region(s) with substantially zero reflectivity to incident light waves, achieved by etching the multilayer completely and filling with a filler material. Consequently, reflective mask 260 is a binary mask, not a phase shift mask. Reflective mask 250 according to embodiments of the disclosure reduces shadowing of the lines that are perpendicular to the incident beam. Further, reflective mask 250 reduces telecentricity errors. Also, reflective mask 250 reduces loss in image contrast due to anodization by any reflective mask coating of the reflective stack.

It should be noted that in the figures, embodiments of lithography masks are depicted with the substrate at the bottom of the figure, and with reflective surfaces and absorber film stacks above the substrate, in keeping with general illustration conventions for such structures. In actual use, the EUV lithography machine may use the EUVL mask face down, with reflective surfaces and absorber stacks facing down rather than up, as EUV light is reflected off the mask to a series of mirrors beneath the mask, with the mirrors reflecting the EUV light to a wafer which may be positioned below the mask.

It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A reflective mask, comprising:
a reflective pattern; and
an absorber pattern embedded within the reflective pattern with a top surface of the absorber pattern being at or below a top surface of the reflective pattern.

2. The reflective mask of claim 1, wherein the reflective pattern includes a plurality of reflective stacks extending from a low thermal expansion material (LTEM) substrate.

3. The reflective mask of claim 2, wherein each of the plurality of reflective stacks has a ruthenium (Ru) cap.

4. The reflective mask of claim 2, wherein each of the plurality of reflective stacks includes at least one molybdenum layer and one silicon layer.

5. The reflective mask of claim 2, wherein the absorber pattern includes an absorber stack extending from the LTEM substrate between a pair of the plurality of reflective stacks, wherein the absorber pattern overlays a fill material between the reflective stacks.

6. The reflective mask of claim 5, wherein the absorber stack includes an absorber layer and an anti-reflective coating over the fill material.

7. The reflective mask of claim 1, wherein the absorber pattern includes an anti-reflective coating overlaying a fill material.

8. The reflective mask of claim 1, wherein the absorber pattern includes a plurality of absorber stacks extending from a low thermal expansion material (LTEM) substrate, each absorber stack extending horizontally between a pair of reflective stacks.

9. The reflective mask of claim 8, wherein the plurality of absorber stacks each includes a fill material, an absorber layer, and an anti-reflective coating.

10. The reflective mask of claim 1, further comprising a plurality of recess wells with each recess well having substantially vertical surfaces separated by a substantially horizontal surface, and wherein the absorber pattern embedded within the reflective pattern includes an absorber layer lining the substantially vertical surfaces and the substantially horizontal surface of the plurality of recess wells.

11. The reflective mask of claim 10, wherein each of the plurality of recess wells has a depth between approximately 100 to 150 nanometers.

12. The reflective mask of claim 1, wherein the absorber pattern has substantially zero reflectivity to incident light wave.

13. A reflective mask, comprising:
a low thermal expansion material (LTEM) substrate;
a pair of reflective stacks, each reflective stack having a first respective top surface extending from the LTEM substrate to a first extent;
a fill stack between the pair of reflective stacks, the fill stack having a second top surface extending from the LTEM substrate to a second extent, the second extent being below the first extent of the pair of reflective stacks, wherein an extended portion of each of the pair of reflective stacks are above the fill stack thereby forming a recess well between the pair of reflective stacks, the recess well having substantially vertical walls separated by the second top surface of the fill stack; and
an absorber layer lining the recess well.

14. The reflective mask of claim 13, further comprising an anti-reflective coating lining the absorber layer in the recess well.

15. The reflective mask of claim 13, wherein each of the pair of reflective stacks has a ruthenium (Ru) cap on top thereof.

16. The reflective mask of claim 13, wherein the pair of reflective stacks each include at least one molybdenum layer and one silicon layer.

17. The reflective mask of claim 13, wherein the absorber layer has zero reflectivity, creating a binary mask with the reflective stacks.

18. A method, comprising:
depositing a fill material onto an extreme ultraviolet (EUV) etched mask, the EUV etched mask including a low thermal expansion material (LTEM) substrate, a pair of reflective stacks, and a trench exposing the LTEM substrate between the pair of reflective stacks, the fill material filling the trench;
forming a recess well by etching the fill material;
depositing an absorber layer over the pair of reflective stacks and in the recess well, wherein a gap remains within the recess well;
depositing a sacrificial fill material over the absorber layer and filling the gap;
planarizing the sacrificial fill material to a top surface of the pair of reflective stacks; and
removing the sacrificial fill material in the gap.

19. The method of claim 18, wherein the pair of reflective stacks each have a ruthenium (Ru) cap, and etching the fill material includes using the Ru caps of the pair of reflective stacks as an etch stop.

20. The method of claim 18, further comprising depositing an anti-reflective coating after depositing the absorber layer, wherein the gap remains in the recess well after depositing the absorber layer and the anti-reflective coating in the recess well
